(19) United States
(12) Patent Application Publication
(10) Pub. No.: US 2026/0262162 A1
(43) Pub. Date: Sep. 3, 2026

(54) CIRCUIT BOARD, DISPLAY PANEL, DISPLAY DEVICE AND MANUFACTURING METHOD

(71) Applicants: Chengdu BOE Optoelectronics Technology Co., Ltd., Chengdu, Sichuan (CN); BOE Technology Group Co., Ltd., Beijing (CN)

(72) Inventors: Xueying HE, Beijing (CN); Mingqiang WANG, Beijing (CN); Zheng BAO, Beijing (CN); Xiangdong WEI, Beijing (CN); Jiaxiang ZHANG, Beijing (CN); Xiaoliang FU, Beijing (CN); Bin ZHANG, Beijing (CN); Zan LUO, Beijing (CN)

(21) Appl. No.: 18/994,589

(22) PCT Filed: Jan. 17, 2024
(86) PCT No.: PCT/CN2024/072666

§ 371 Date: Jan. 14, 2025

(30) Foreign Application Priority Data
Feb. 7, 2023 (CN) 202310128525.2

(51) Int. Cl. H05K 1/02

(52) U.S. Cl. CPC H05K 1/0298; H05K 1/0218

(57) ABSTRACT

The present disclosure relates to a circuit board, a display panel, a display device and a manufacturing method. The circuit board includes a first end portion and a second end portion disposed opposite to each other along a thickness direction; the circuit board further includes metal wiring layers and a connection layer; the number of the metal wiring layers is at least three, which are a first wiring layer, a second wiring layer and a third wiring layer respectively. The connection layer includes a lateral extension portion and a vertical extension portion which are electrically connected, at least part of the structure of the lateral extension portion is located in the first wiring layer, one end of the vertical extension portion is connected to the lateral extension portion, and the other end thereof extends to the third wiring layer close to the second wiring layer.

### TECHNICAL FIELD

The present disclosure relates to the field of display technologies, and in particular to a circuit board, a display panel, a display device and a manufacturing method.

### BACKGROUND

An existing electronic device generally includes a circuit board and a display module, and the circuit board and the display module are electrically connected through a bonding process, to control the display module by the circuit board. However, breakage and copper exposure are prone to occur in a shielding layer on the outside of the circuit board. Meanwhile, once the shielding layer is damaged, ESD (Electro-Static Discharge) resistance and EMI (Electro Magnetic Interference) resistance of the circuit board are seriously affected.

### SUMMARY

An object of the present disclosure is to provide a circuit board, a display panel, a display device and a manufacturing method, which can improve the integrity of the structure in the circuit board.

According to a first aspect of an embodiment of the present disclosure, a circuit board is provided, the circuit board includes a first end portion and a second end portion disposed opposite to each other along a thickness direction; and the circuit board further includes: metal wiring layers, the number of the metal wiring layers is at least three, a metal wiring layer of the metal wiring layers close to the first end portion is a first wiring layer, a metal wiring layer of the metal wiring layers close to the second end portion is a second wiring layer, and one or more metal wiring layers of the metal wiring layers located between the first wiring layer and the second wiring layer are located in a third wiring layer; and a connection layer, including a lateral extension portion and a vertical extension portion that are electrically connected to each other, at least a part of the lateral extension portion is located in the first wiring layer, one end of the vertical extension portion is connected to the lateral extension portion, and the other end of the vertical extension portion extends to the third wiring layer.

Optionally, an end surface of the first wiring layer away from the third wiring layer is recessed downward to form a grounding sinking-groove, and the at least part of the lateral extension portion is located in the grounding sinking-groove.

Optionally, the grounding sinking-groove includes a bottom surface, the bottom surface is recessed downward to form a vertical sinking-groove, the vertical sinking-groove communicates with the grounding sinking-groove, and in the thickness direction, an area of a projection of the vertical sinking-groove on the second wiring layer is less than an area of a projection of the grounding sinking-groove on the second wiring layer.

Optionally, a ratio of a thickness of the grounding sinking-groove to a thickness of the first wiring layer is greater than or equal to ⅕ and less than or equal to ⅘.

Optionally, an end surface of the connection layer away from the second wiring layer is a first end surface, and an end surface of the first wiring layer away from the second wiring layer is a second end surface; and the first end surface is farther away from the second wiring layer than the second end surface, and a distance from the first end surface to the second end surface is less than or equal to 50 micrometers.

Optionally, the first end surface is recessed along a direction from the first wiring layer to the second wiring layer to form a groove.

Optionally, a depth of the groove is less than the distance from the first end surface to the second end surface.

Optionally, the circuit board includes an encapsulation module, and the encapsulation module is disposed at a side of the first wiring layer away from the second wiring layer; an area of a projection of the first wiring layer on the second wiring layer is less than an area of a projection of the third wiring layer on the second wiring layer, and the first wiring layer and the encapsulation module located on the first wiring layer form a convex island; and a projection of the convex island on the second wiring layer covers a projection of the connection layer on the second wiring layer.

Optionally, the circuit board includes a bending region, and the circuit board is capable of being bent in the bending region to form a crease; the convex island is located in the bending region, and a minimum distance from the crease to the convex island is greater than or equal to 0.1 mm; and/or, an area of a projection of the lateral extension portion on the second wiring layer is a first area, an area of a projection of the first wiring layer located in the convex island on the second wiring layer is a second area, a ratio of the first area to the second area is greater than or equal to ¼ and less than or equal to ½.

Optionally, along the thickness direction, an area of a projection of the lateral extension portion on the second wiring layer is greater than or equal to 0.001 square millimeters and less than or equal to 0.1 square millimeters.

Optionally, the connection layer further includes a connection portion located in the third wiring layer and electrically connected to the third wiring layer; and one end of the vertical extension portion is connected to the lateral extension portion, and the other end of the vertical extension portion extends to the connection portion.

Optionally, an area of a projection of the vertical extension portion on the second wiring layer is less than an area of a projection of the connection portion on the second wiring layer; and/or an area of a projection of the lateral extension portion on the second wiring layer coincides with and is the same as an area of a projection of the connection portion on the second wiring layer.

According to a second aspect of an embodiment of the present disclosure, there is provided a display panel, including a display module and the above circuit board, and the display module is electrically connected to the circuit board.

According to a third aspect of an embodiment of the present disclosure, there is provided a display device including a housing and the above display panel, and the display panel is fixed to the housing.

According to a dead aspect of an embodiment of the present disclosure, there is provided a method for manufacturing a circuit board, the manufacturing method is used for manufacturing the above circuit board; the manufacturing method includes: providing a die, the die includes at least three metal wiring layers, a metal wiring layer of the metal wiring layers close to the first end portion is a first wiring layer, a metal wiring layer of the metal wiring layers close to the second end portion is a second wiring layer, and one or more metal wiring layers of the metal wiring layers located between the first wiring layer and the second wiring layer are located in a third wiring layer; drilling a side of the die away from the second wiring layer, and forming a first sinking-groove in the die, the first sinking-groove extending to the third wiring layer; drilling the side of the die away from the second wiring layer again, and forming a grounding sinking-groove in the die, wherein the grounding sinking-groove is located in the first wiring layer, and a projection of the grounding sinking-groove on the second wiring layer covers a projection of the first sinking-groove on the second wiring layer; and forming a connection layer in the first sinking-groove and the grounding sinking-groove, wherein a part of the connection layer located in the grounding sinking-groove is a lateral extension portion, and the other part of the connection layer is a vertical extension portion, one end of the vertical extension portion is connected to the lateral extension portion, and the other end of the vertical extension portion extends to the third wiring layer.

The circuit board, the display panel, the display device and the manufacturing method are provided. At least part of the structure of the lateral extension portion in the circuit board is located in the first wiring layer, so that the first wiring layer and the connecting layer are prevented from forming a stepped surface with a large slope, the stepped surface with the large slope is prevented from puncturing the film layers located on the sides, away from the second wiring layer, of the first wiring layer and the connecting layer, and the structural integrity of the circuit board is further ensured.

It should be understood that the foregoing general description and the following detailed description are merely exemplary and explanatory, and do not limit the present disclosure.

### BRIEF DESCRIPTION OF DRAWINGS

The accompanying drawings, which are incorporated in and constitute a part of this specification, illustrate embodiments consistent with the present disclosure and, together with the description, serve to explain away from the present disclosure.

FIG. 1 is a schematic structural diagram of an electronic device according to an embodiment of the present disclosure;

FIG. 2 is a schematic structural diagram of a circuit board;

FIG. 3 is a schematic structural diagram of a circuit board in an electronic device according to an embodiment of the present disclosure;

FIG. 4 is a schematic structural diagram of a circuit board in an electronic device according to another embodiment of the present disclosure;

FIG. 5 is a flowchart of a method for manufacturing a circuit board according to an embodiment of the present disclosure;

FIG. 6 is a schematic structural diagram of a circuit board in an electronic device during manufacturing according to an embodiment of the present disclosure;

FIG. 7 is another schematic structural diagram of a circuit board in an electronic device during manufacturing according to an embodiment of the present disclosure;

FIG. 8 is still another schematic structural diagram of a circuit board in an electronic device during manufacturing according to an embodiment of the present disclosure;

FIG. 9 is still yet another schematic structural diagram of a circuit board in an electronic device during manufacturing according to an embodiment of the present disclosure;

FIG. 10 is still yet another schematic structural diagram of a circuit board in an electronic device during manufacturing according to an embodiment of the present disclosure;

FIG. 11 is still yet another schematic structural diagram of a circuit board in an electronic device during manufacturing according to an embodiment of the present disclosure;

FIG. 12 is a schematic structural diagram of a circuit board in an electronic device according to another embodiment of the present disclosure;

FIG. 13 is a schematic structural diagram of a circuit board in an electronic device during manufacturing according to another embodiment of the present disclosure; and

FIG. 14 is another schematic structural diagram of a circuit board in an electronic device during manufacturing according to another embodiment of the present disclosure.

### DESCRIPTION OF REFERENCE SIGNS IS AS FOLLOWS

electronic device 1; display panel 10; housing 20; circuit board 100; first end portion 101; second end portion 102; bending region 103; die 104; first sinking-groove 105; carbon powder particle 106; convex island 107; metal wiring layer 200; first wiring layer 210; grounding sinking-groove 211; vertical sinking-groove 212; second end surface 213; second wiring layer 220; third wiring layer 230; third sinking-groove 231; connection layer 300; first end surface 301; groove 302; lateral extension portion 310; vertical extension portion 320; connection portion 330; cover layer 400; shielding layer 500; insulating layer 600; oxidation layer 700; encapsulation module 800; display module 900; thickness direction H.

### DETAILED DESCRIPTION

Exemplary embodiments, examples of which are illustrated in the accompanying drawings, will be described in detail herein. When the following description refers to the drawings, like numerals in different drawings indicate the same or similar elements, unless otherwise indicated. The embodiments described in the following exemplary embodiments do not represent all embodiments consistent with the present disclosure. Rather, they are merely examples of devices and methods consistent with some aspects of the present disclosure as detailed in the appended claims.

The term used in the present disclosure is for the purpose of describing particular embodiments only and is not intended to be limiting of the present disclosure. Technical terms or scientific terms used in the present disclosure should have general meanings as understood by one of ordinary skill in the art to which the present disclosure belongs, unless otherwise defined. Terms such as “one”, “a/an”, or the like, used in the specification and claims of the present disclosure do not represent a quantity limitation, but represent that there is at least one. “Multiple” or “a plurality of” means two or more. Terms such as “comprise”, “include”, or the like, mean that an element or item appearing before “comprise” or “include” covers elements or items and equivalents thereof listed after “comprise” or “include”, without excluding other elements or items. Terms “connect”, “connect with each other”, or the like, are not limited to physical or mechanical connections, and may include electrical connections, whether direct or indirect. Similar terms such as “upper” and/or “lower” are for ease of description only and are not limited to a position or a spatial orientation. As used in this specification and the appended claims, the singular forms “a/an”, “said”, and “the” are also intended to include plural forms unless clearly indicated otherwise in the context. It should also be understood that the term “and/or” as used herein refers to and includes any or all possible combinations of one or more associated listed items.

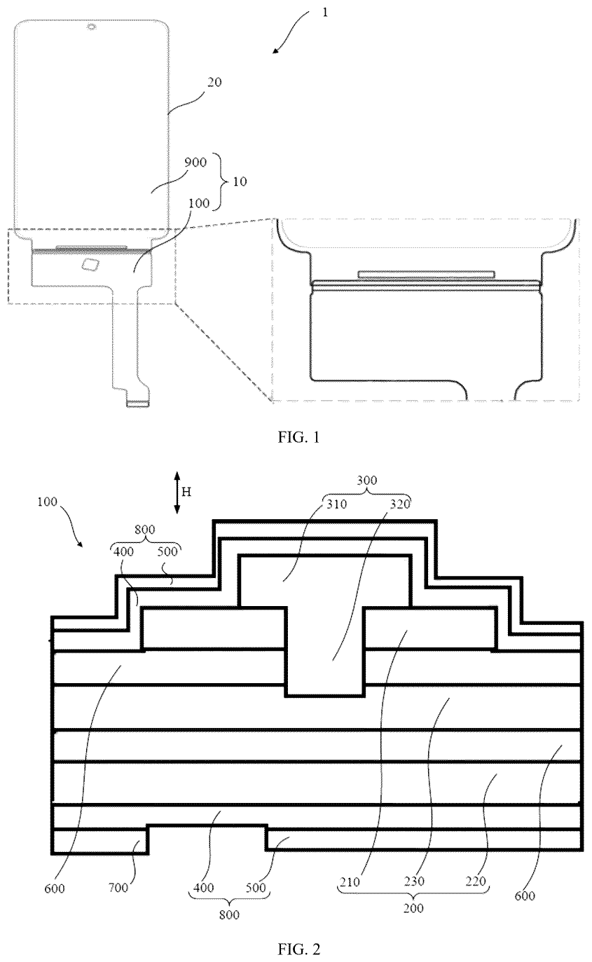

As shown in FIGS. 1-11, the present disclosure provides an electronic device 1. The electronic device 1 may be a smart wearable device (for example, a watch or a bracelet) with a display panel 10 and capable of performing smart display, and of course, may also be a device with the display panel 10 and capable of performing smart display, such as a mobile phone, a tablet computer, a desktop computer, or the like. FIG. 1 shows a mobile phone including the above display panel 10 and a housing 20, and the display panel 10 is fixed to the housing 20. The display panel 10 specifically includes a display module 900 and a circuit board 100, both the display module 900 and the circuit board 100 have bonding regions, and a bonding process is performed on the bonding regions of the display module 900 and the circuit board 100 to achieve electrical connection between the display module 900 and the circuit board 100.

As shown in FIG. 1 and FIG. 2, the display panel 10 in the current electronic device 1 (smart wearable device) may be in a bent form. In this case, in order to adapt to an anisotropic space in the electronic device 1, a flexible circuit board 100 or a circuit board 100 having a specific shape may be used, and this circuit board 100 has a characteristic of being freely bent, wound or folded, or may be bent, wound or folded at a specific position. In order to adapt to the bending, winding or folding performance, it is necessary to perform a thickness thinning process on at least part of the region (the region that can be bent, wound or folded) in the current flexible circuit board 100, so as to avoid the situation that the corresponding region is broken due to the thick thickness during the bending, winding or folding operation. However, in order to reduce the thickness of the designated region, a metal wiring layer 200 of an upper layer of the circuit board 100 may be etched. In this case, the metal wiring layer 200 and other metal layers located on the metal wiring layer 200 may have a plurality of stepped surfaces, and the step has a large slope, which is prone to puncture or scratch a shielding layer 500 located on the outer side of the circuit board 100, resulting in the breakage and copper exposure of the shielding layer 500, thereby affecting the ESD (Electro-Static Discharge) resistance and the EMI (Electro Magnetic Interference) resistance of the circuit board 100.

In order to solve the above problems, the inventors have made the following improvements.

As shown in FIG. 3, the circuit board 100 includes a metal wiring layer 200, a connection layer 300, a cover layer 400 (CoverLay, CVL), a shielding layer 500, an insulating layer 600 (Polyimide, PI) and an oxidation layer 700. The number of the metal wiring layers 200 is at least three, the plurality of metal wiring layers 200 are spaced apart along a thickness direction H, and the insulating layer 600 is disposed between adjacent metal wiring layers 200. The circuit board 100 includes a first end portion 101 and a second end portion 102 disposed opposite to each other in the thickness direction H. A side of one of the metal wiring layers 200 located at the first end portion 101 away from the second end portion 102 is covered with the cover layer 400 and the shielding layer 500, and the shielding layer 500 is disposed outside the cover layer 400, that is, disposed at a side of the cover layer 400 away from the metal wiring layer 200. The connection layer 300 is configured to electrically connect different metal wiring layers 200 to implement signal interaction between the different metal wiring layers 200. A side of one of the metal wiring layers 200 located at the second end portion 102 away from the first end portion 101 is also covered with the cover layer 400 and the shielding layer 500, and the shielding layer 500 is disposed outside the cover layer 400, that is, disposed at a side of the cover layer 400 away from the metal wiring layer 200. The oxidation layer 700 is used to protect the metal wiring layers 200 in the middle from being oxidized. In this embodiment, the oxidation layer 700 is disposed on the second end portion 102 of the circuit board 100, and is disposed outside the cover layer 400. The oxidation layer 700 is spaced apart from the shielding layer 500 on the peripheral side of the oxidation layer 700 by a certain distance. Of course, in other embodiments, the oxidation layer 700 is disposed on the first end portion 101 of the circuit board 100. It should be noted that the oxidation layer 700 may be formed by an electroless nickel/immersion gold (ENIG) process or a nickel/gold electroplating process.

It should be noted that, in the present embodiment, the first end portion 101 is an end close to the bonding region of the display module 900 along the thickness direction of the circuit board 100, and the bonding process is performed through the first end portion 101 and the display module 900 to realize the electrical connection between the display module 900 and the circuit board 100. Of course, in other embodiments, the second end portion 102 may be close to the bonding region of the display module 900 along the thickness direction of the circuit board 100, and the bonding process is performed through the second end portion 102 and the display module 900, so as to realize the electrical connection between the display module 900 and the circuit board 100.

As shown in FIG. 1, one of the metal wiring layers 200 close to the first end portion 101 is referred to as a first wiring layer 210, one of the metal wiring layers 200 close to the second end portion 102 is referred to as a second wiring layer 220, and one or more of the metal wiring layers 200 located between the first wiring layer 210 and the second wiring layer 220 are located in a third wiring layer 230. In this embodiment, the number of the third wiring layers 230 is merely one, and of course, in other embodiments, the number of the third wiring layers 230 may also be two, three or more. In some embodiments, a structure on the first wiring layer 210 is used as a connection pin of the bonding region, or the first wiring layer 210 is connected to the connection pin of the bonding region. Of course, in other embodiments, the third wiring layer 230 or the second wiring layer 220 may also be used as the connection pin of the bonding region, or the third wiring layer 230 or the second wiring layer 220 may be connected to the connection pin of the bonding region.

The connection layer 300 includes a lateral extension portion 310 and a vertical extension portion 320 that are electrically connected to each other. The vertical extension portion 320 has a component in the thickness direction H for extending to the third wiring layer 230 in the thickness direction H. An extending direction of the lateral extension portion 310 is perpendicular to an extending direction of the vertical extension portion 320, and is configured to be electrically connected to the first wiring layer 210.

The above-mentioned defects of the prior art are further described with reference to FIG. 2. In one design, the lateral extension portion 310 is directly disposed at an end of the first wiring layer 210 away from the second wiring layer 220, and in this case, a stepped surface with a large vertical height difference (the height difference is the thickness of the lateral extension portion 310) is formed between the lateral extension portion 310 and the end of the first wiring layer 210 away from the second wiring layer 220. When the area of the first wiring layer 210 is reduced and smaller than that of the insulating layer 600 adjacent to the first wiring layer 210, the end of the first wiring layer 210 away from the second wiring layer 220 and an end of the insulating layer 600 adjacent to the first wiring layer 210 away from the second wiring layer 220 also form a stepped surface with a large vertical height difference (the height difference is the thickness of the lateral first wiring layer 210). In this case, there are more stepped surfaces in the circuit board 100; due to the large height difference of the step, the slope of the step is too large; and at the corner position of the stepped surface, it is prone to puncture or scratch the shielding layer 500 located on the outer side of the circuit board 100, resulting in damage to the shielding layer 500 and copper exposure, thereby affecting the ESD resistance and EMI resistance of the circuit board 100.

As shown in FIG. 3, in the present disclosure, at least part of the structure of the lateral extension portion 310 is located in the first wiring layer 210, one end of the vertical extension portion 320 is connected to the lateral extension portion 310, and the other end thereof extends to the third wiring layer 230. In the present embodiment, the number of third wiring layers 230 is one, and the vertical extension portion 320 extends to the third wiring layer 230 to electrically connect the first wiring layer 210 and the third wiring layer 230.

In the above structure, the end surface of the lateral extension portion 310 away from the second wiring layer 220 may be referred to as the first end surface 301, and the end surface of the first wiring layer 210 away from the second wiring layer 220 may be referred to as the second end surface 213.

When at least part of the structure of the lateral extension portion 310 in the circuit board 100 is located in the first wiring layer 210, and the positional relationship between the first end surface 301 and the second end surface 213 may be at least one of the following relationships: a plane where the first end surface 301 is located is flush with a plane where the second end surface 213 is located; the first end surface 301 is farther away from the second wiring layer 220 than the second end surface 213; and the first end surface 301 is closer to the second wiring layer 220 than the second end surface 213. When the planes where the first end surface 301 and the second end surface 213 are located are flush with each other, there is no height difference between the lateral extension portion 310 and the end of the first wiring layer 210 away from the second wiring layer 220. When the planes where the first end surface 301 and the second end surface 213 are located are not flush with each other, the height difference between the lateral extension portion 310 and the end of the first wiring layer 210 away from the second wiring layer 220 is also less than the height difference in the technical solution corresponding to FIG. 2. Through the above arrangement, the occurrence of the stepped surface with an excessively large height difference is avoided, so as to prevent the first wiring layer 210 and the connection layer 300 from forming a stepped surface with a large slope, thereby preventing the stepped surface with the large slope from puncturing the film layers (including the cover layer 400 and the shielding layer 500) located on the sides of the first wiring layer 210 and the connection layer 300 away from the second wiring layer 220, ensuring the structural integrity of the circuit board 100, and ensuring that the circuit board 100 has better ESD resistance and EMI resistance.

Optionally, as shown in FIG. 3 and FIG. 8, an end surface of the first wiring layer 210 away from the third wiring layer 230 is recessed downward to form a grounding sinking-groove 211, and at least part of the structure of the lateral extension portion 310 is located in the grounding sinking-groove 211. With the above arrangement, at least part of the lateral extension portion 310 may be formed inside the first wiring layer 210.

As shown in FIG. 3, the grounding sinking-groove 211 includes a bottom surface, the bottom surface is recessed downward to form a vertical sinking-groove 212, the vertical sinking-groove 212 communicates with the grounding sinking-groove 211, and along the thickness direction H, an area of a projection of the vertical sinking-groove 212 on the second wiring layer 220 is less than an area of a projection of the grounding sinking-groove 211 on the second wiring layer 220. In the above arrangement, the area of the projection of the grounding sinking-groove 211 is greater than the area of the projection of the vertical sinking-groove 212, thereby ensuring that the area of the projection of the lateral extension portion 310 is greater than the area of the projection of the vertical extension portion 320, and further ensuring that the area of the lateral extension portion 310 is greater, so as to better electrically connect the first wiring layer 210 and the lateral extension portion 310. Meanwhile, it is ensured that the area of the vertical extension portion 320 is within a controllable range to reduce the cost.

The inventors have found that when a ratio of a thickness hl of the grounding sinking-groove 211 to a thickness h2 of the first wiring layer 210 is too small, the contact area between the lateral extension portion 310 in the grounding sinking-groove 211 and the first wiring layer 210 is affected, which cannot ensure the effective electrical connection between and the combination stability of the lateral extension portion 310 and the first wiring layer 210. When the ratio of the thickness hl of the grounding sinking-groove 211 to the thickness h2 of the first wiring layer 210 is too large, the thickness of the portion of the first wiring layer 210 provided with the grounding sinking-groove 211 is too thin, so that the structural stability of the first wiring layer 210 cannot be ensured. A large number of experiments made by the inventor indicate that when the ratio of the thickness h1 of the grounding sinking-groove 211 to the thickness h2 of the first wiring layer 210 is greater than or equal to ⅕ and less than or equal to ⅘, the effective electrical connection between the first wiring layer 210 and the connection layer 300 can be ensured, the stability of the combination of the first wiring layer 210 and the connection layer 300 is ensured, and meanwhile, the structural stability of the first wiring layer 210 is ensured.

An end surface of the connection layer 300 away from the second wiring layer 220 is the first end surface 301, and an end surface of the first wiring layer 210 away from the second wiring layer 220 is the second end surface 213. The first end surface 301 is farther away from the second wiring layer 220 than the second end surface 213, and a distance d1 from the first end surface 301 to the second end surface 213 is less than or equal to 50 μm. In the manufacturing process, it is generally difficult to achieve that the plane where the first end surface 301 is located is flush with the plane were the second end surface 213 is located. The inventors have found through experiments that when the distance d1 between the first end surface 301 and the second end surface 213 is controlled within the above range, an excessive step difference between the lateral extension portion 310 of the connection layer 300 and the first wiring layer 210 can be avoided, thereby preventing the shielding layer 500 and the cover layer 400 covered thereon from being punctured. Therefore, the structural integrity of the circuit board 100 is ensured, and the circuit board 100 has better ESD resistance and EMI resistance.

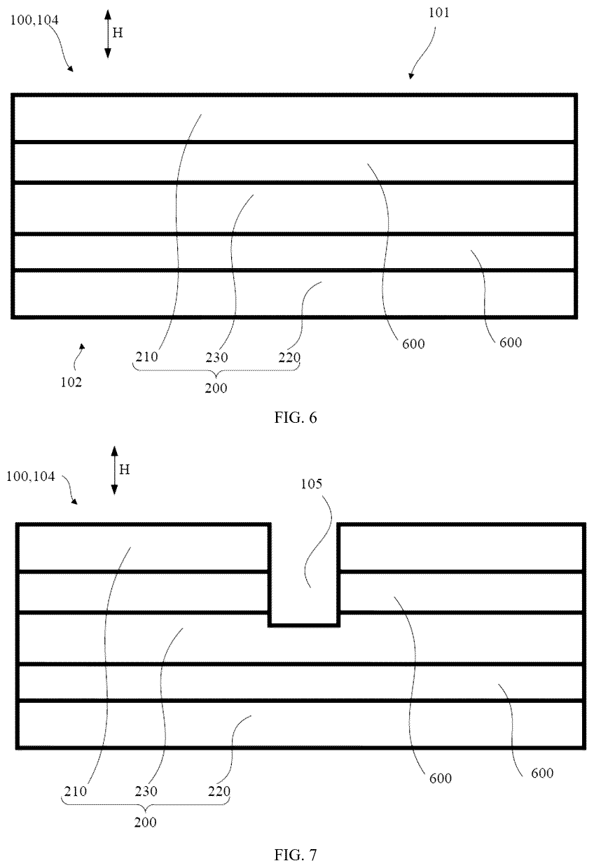

As shown in FIG. 3 and FIG. 6, an area of a projection of the first wiring layer 210 on the second wiring layer 220 is less than an area of a projection of the third wiring layer 230 on the second wiring layer 220. In other words, when the circuit board 100 is manufactured, a structure of a die 104 is first obtained, and metal wiring layers 200 are disposed in the structure of the die 104. For example, the metal wiring layers 200 have the same size. Thereafter, each film layer structure is formed on the die 104 structure to obtain the above circuit board 100. In the manufacturing process, the size of the first wiring layer 210 needs to be reduced, so that the area of the projection of the first wiring layer 210 on the second wiring layer 220 is less than the area of the projection of the third wiring layer 230 on the second wiring layer 220. In the above structure, by reducing the lateral dimension of the first wiring layer 210, the thickness of the circuit board 100 at the corresponding position is reduced, so that when the circuit board 100 is bent, wound or folded at this position, the circuit board 100 is prevented from being broken at this position due to the thicker thickness. In other words, by reducing the thickness of the circuit board 100 at the corresponding position, the flexible deformation capability at the corresponding position is improved.

As shown in FIG. 3, in the present embodiment, the whole formed by the cover layer 400 and the shielding layer 500 may be used as an encapsulation module 800, and the encapsulation module 800 is disposed at a side of the first wiring layer 210 away from the second wiring layer 220. When the size of the first wiring layer 210 is smaller, the first wiring layer 210 and the encapsulation module 800 located above the first wiring layer 210 protrude upward to form a convex island 107. The projection of the convex island 107 on the second wiring layer 220 covers the projection of the connection layer 300 on the second wiring layer 220. In other words, the connection layer 300 also serves as at least a partial structure of the convex island 107.

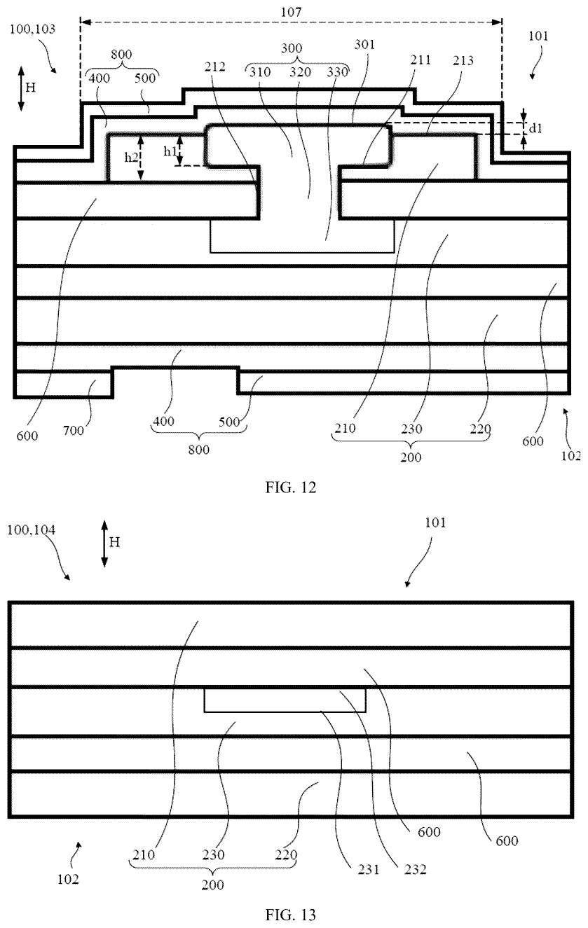

In other embodiments, as shown in FIG. 12, the connection layer 300 may further include a connection portion 330. The connection portion 330 is located in the third wiring layer 230 and electrically connected to the third wiring layer 230. One end of the vertical extension portion 320 is electrically connected to the lateral extension portion 310, and the vertical extension portion 320 extends to the connection portion 330. Through the above arrangement, the contact area between the connection layer 300 and the third wiring layer 230 can be increased, the stability of the connection structure between the connection layer 300 and the third wiring layer 230 can be improved, and meanwhile, the stability of the electrical connection between the connection layer 300 and the third wiring layer 230 can be ensured.

In this embodiment, the area of the projection of the vertical extension portion 320 on the second wiring layer 220 is less than an area of a projection of the connection portion 330 on the second wiring layer 220. In addition, the area of the projection of the lateral extension portion 310 on the second wiring layer 220 and the area of the projection of the connection portion 330 on the second wiring layer 220 coincide with each other and are the same. In the above arrangement, better electrical connection between the second wiring layer and the first wiring layer 210 can be ensured. Meanwhile, the tightness of the connection between the connection layer 300 and the overall structure is ensured.

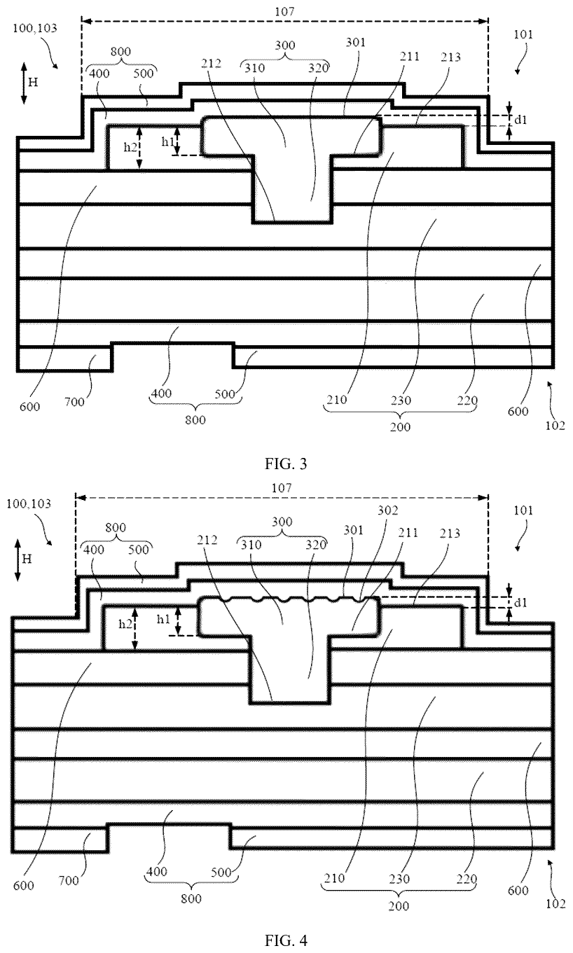

Optionally, as shown in FIG. 4, the first end surface 301 is recessed downward to form a groove 302. In other words, the first end surface 301 is recessed along a direction from the first wiring layer 210 to the second wiring layer 220 to form the groove 302. The groove 302 may be a curved groove as shown in FIG. 4, or may be a wavy groove. By providing the groove 302, the contact area between the cover layer 400 and the connection layer 300 can be increased, and the bonding between the cover layer 400 and the connection layer 300 can be enhanced. Meanwhile, providing the groove 302 can also reduce the local height of the convex island 107, so as to disperse stress and avoid or reduce the possibility of breakage. In this embodiment, a depth of the groove 302 is less than the distance d1 from the first end surface 301 to the second end surface 213. Through the above arrangement, the flatness of the cover layer 400 and the shielding layer 500 formed above the connection layer 300 is ensured as much as possible.

The circuit board 100 includes a bending region 103, and the circuit board 100 can be bent in the bending region 103 to form a crease. The convex island 107 is located in the bending region 103, and a minimum distance from the crease to the convex island 107 is greater than or equal to 0.1 mm. Through the above arrangement, the problem that the film layer in the convex island 107 is damaged due to the too small distance between the convex island 107 and the crease is avoided.

Optionally, the area of the projection of the lateral extension portion 310 on the second wiring layer 220 is referred to as a first area, the area of the projection of the first wiring layer 210 located in the convex island 107 on the second wiring layer 220 is referred to as a second area, and a ratio of the first area to the second area is greater than or equal to ¼ and less than or equal to ½. In the above arrangement, by controlling the minimum value of the ratio of the first area to the second area, the contact area between the lateral extension portion 310 and the first wiring layer 210 can be ensured, thereby ensuring stable and effective electrical connection between the lateral extension portion 310 and the first wiring layer 210. By starting to the maximum value of the ratio of the first area to the second area, the size of the lateral extension portion 310 can be prevented from being too large, thereby effectively controlling the cost.

Optionally, along the thickness direction H, the area of the projection of the lateral extension portion 310 on the second wiring layer 220 is greater than or equal to 0.001 square millimeters and less than or equal to 0.1 square millimeters. According to the above analysis, on the premise of the existing process technology, it is difficult to achieve that the first end surface 301 of the lateral extension portion 310 is flush with the second end surface 213 of the first wiring layer 210, and the lateral extension portion 310 slightly protrudes from the first wiring layer 210, so that the convex island 107 forms a small bump protruding upward at a corresponding position. In the above structure, by controlling the area of the projection of the lateral extension portion 310 on the second wiring layer 220, that is, the minimum value of the first area, the problem that the film layer in the bump structure is damaged due to the case that the small bump raised on the convex island 107 is too small is avoided.

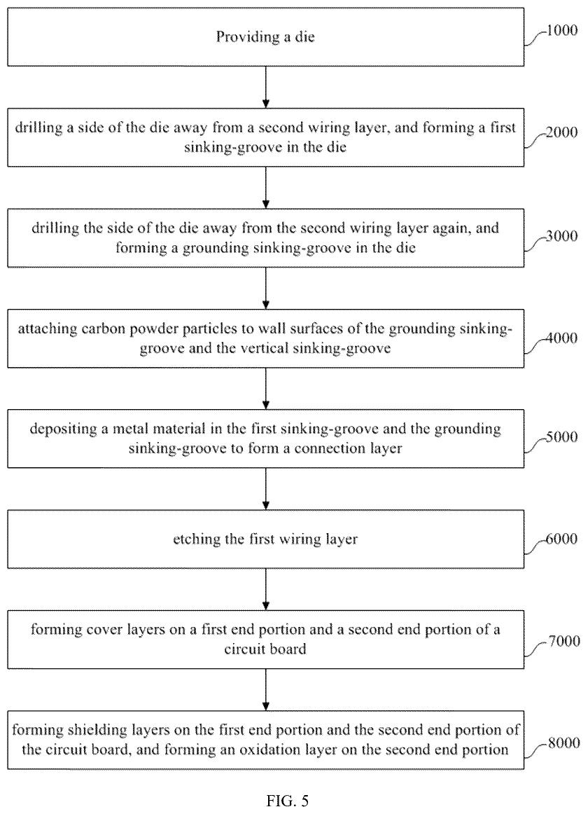

As shown in FIG. 5, this disclosure further provides a manufacturing method of the circuit board 100, and the manufacturing method is used to manufacture the circuit board 100 mentioned above.

The manufacturing method specifically includes the following steps.

As a step 1000, a die 104 is provided (see FIG. 6, in conjunction with FIG. 3 if necessary).

The die 104 includes at least three metal wiring layers 200. One of the metal wiring layers 200 close to the first end portion 101 is referred to as the first wiring layer 210, one of the metal wiring layers 200 close to the second end portion 102 is referred to as the second wiring layer 220, and one or more metal wiring layers of the metal wiring layers 200 located between the first wiring layer 210 and the second wiring layer 220 are located in the third wiring layer 230. An insulating layer 600 is further disposed between adjacent metal wiring layers 200.

At a step 2000, a side of the die 104 away from the second wiring layer 220 is drilled, a first sinking-groove 105 is formed in the die 104, and the first sinking-groove 105 extends to the third wiring layer 230 (referring to FIG. 7, in conjunction with FIG. 3 if necessary).

In this embodiment, the first sinking-groove 105 may be formed by a high-energy UV laser ray cutting. In addition, the first sinking-groove 105 extends into the third wiring layer 230. Of course, in other embodiments, the first sinking-groove 105 may also extend to an end surface of the third wiring layer 230 away from the second wiring layer 220.

At a step 3000, the side of the die 104 away from the second wiring layer 220 is drilled again, and a grounding sinking-groove 211 is formed in the die 104. The grounding sinking-groove 211 is located in the first wiring layer 210, and a projection of the grounding sinking-groove 211 on the second wiring layer 220 covers a projection of the first sinking-groove 105 on the second wiring layer 220 (referring to FIG. 8, in conjunction with FIG. 3 if necessary). In other words, an area of a cross-section of the grounding sinking-groove 211 is greater than an area of a cross-section of the first sinking-groove 105.

In this embodiment, the grounding sinking-groove 211 may be formed by the high-energy UV laser ray cutting again. In this case, a part of the structure of the first sinking-groove 105 is located in the grounding sinking-groove 211, and the other part of the structure serves as the vertical sinking-groove 212 mentioned above. In this embodiment, the shape of the grounding sinking-groove 211 is circular. Of course, the cross-sectional shape of the grounding sinking-groove 211 is not unique. The cross-sectional shape of the grounding sinking-groove 211 can be changed by changing a shape of a tool. In other embodiments, the cross-sectional shape of the grounding sinking-groove 211 may be square, oval, rectangular, or other shapes.

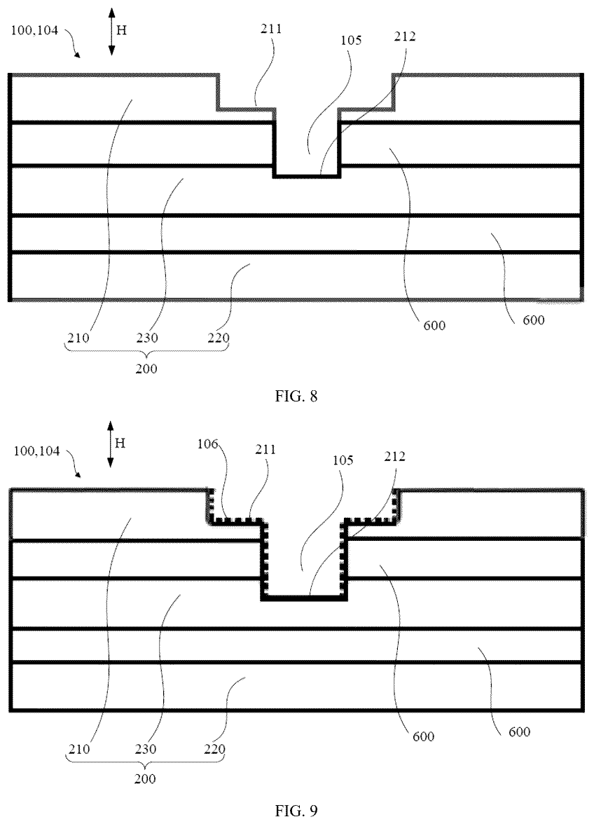

At a step 4000, carbon powder particles 106 are attached to wall surfaces of the grounding sinking-groove 211 and the vertical sinking-groove 212 (as shown in FIG. 9, in combination with FIG. 3 if necessary).

The carbon powder particles 106 are conductive substance, and are deposited on the wall surfaces of the grounding sinking-groove 211 and the vertical sinking-groove 212, which is beneficial to forming a wiring layer in the grounding sinking-groove 211 and the vertical sinking-groove 212 smoothly.

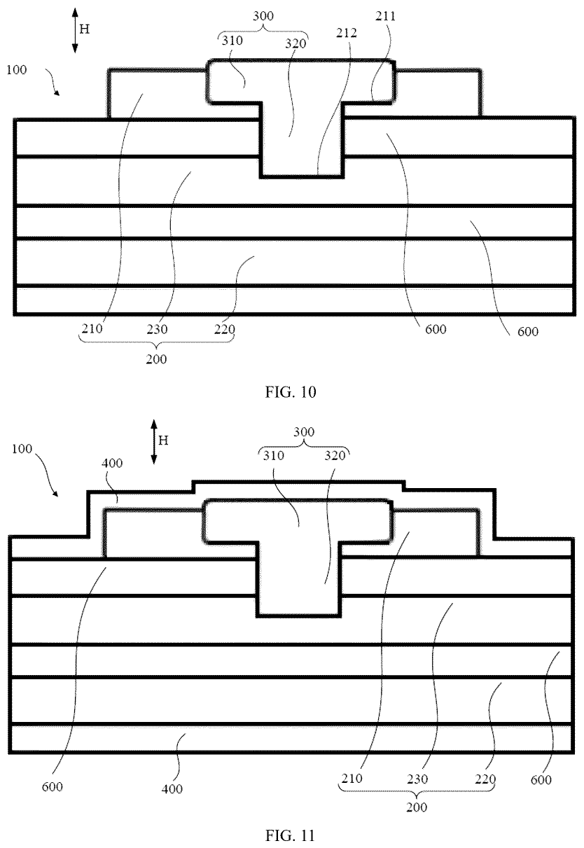

At a step 5000, a metal material is deposited in the first sinking-groove 105 and the grounding sinking-groove 211 to form a connection layer 300. A portion of the connection layer 300 located in the grounding sinking-groove 211 is referred to as a lateral extension portion 310, other portion of the connection layer 300 is referred to as a vertical extension portion 320, one end of the vertical extension portion 320 is connected to the lateral extension portion 310, and the other end of the vertical extension portion 320 extends to the third wiring layer 230 (referring to FIG. 10, in combination with FIG. 3 if necessary).

Through the above arrangement, the third wiring layer 230 is electrically connected to the first wiring layer 210 through the connection layer 300. In this case, since the grounding sinking-groove 211 is located in the first wiring layer 210, the occurrence of a stepped surface with an excessively large height difference is avoided, so as to prevent the first wiring layer 210 and the connection layer 300 from forming a stepped surface with a large slope, thereby preventing the stepped surface with the large slope from puncturing a film layer located at sides of the first wiring layer 210 and the connection layer 300 away from the second wiring layer 220, ensuring the structural integrity of the circuit board 100, and ensuring that the circuit board 100 has better ESD resistance and EMI resistance.

At a step 6000, the first wiring layer 210 is etched to reduce the area of the first wiring layer 210 (referring to FIG. 10, in combination with FIG. 3 if necessary).

In the above steps, by reducing the lateral dimension of the first wiring layer 210, the thickness of the circuit board 100 at the corresponding position is reduced, so that when the circuit board 100 is bent, wound or folded at this position, the circuit board 100 is prevented from being broken at this position due to the thicker thickness. In other words, by reducing the thickness of the circuit board 100 at the corresponding position, the flexible deformation capability at the corresponding position is improved.

In this embodiment, the step of reducing the area of the first wiring layer 210 is performed after the step of forming the connection layer 300. Of course, in other embodiments, the step of reducing the area of the first wiring layer 210 may be performed before the step of forming the connection layer 300.

At a step 7000, cover layers 400 are individually formed on the first end portion 101 and the second end portion 102 of the circuit board 100 (as shown in FIG. 11, in combination with FIG. 3 if necessary).

Specifically, forming the cover layer 400 on the first end portion 101 of the circuit board 100 includes: forming the cover layer 400 on an end of the first wiring layer 210 away from the second wiring layer 220, a portion, exposed by etching the first wiring layer 210, of the insulating layer 600 adjacent to the first wiring layer 210, and an end surface, away from the second wiring layer 220, of a portion of the connection layer 300 exposed in the first wiring layer 210. The cover layer 400 may protect the film layer structure located therein.

At a step 8000, shielding layers 500 are individually formed on the first end portion 101 and the second end portion 102 of the circuit board 100, and an oxidation layer 700 is formed on the second end portion 102 (referring to FIG. 3).

Specifically, the shielding layer 500 is formed on an end, away from the second wiring layer 220, of the cover layer 400 located at the first end portion 101. Another shielding layer 500 is formed on an end, away from the first wiring layer 210, of the cover layer 400 located at the second end 102. Meanwhile, the oxidation layer 700 is formed on an end, away from the first wiring layer 210, of the cover layer 400 located at the second end portion 102, and a gap exists between the oxidation layer 700 and the shielding layer 500.

Through the above arrangement, it is avoided that the step with the large slope appears in the circuit board 100, thereby avoiding or reducing the risk that the shielding layer 500 and the cover layer 400 are punctured, and further ensuring that the shielding layer 500 has effective ESD resistance and EMI resistance.

As shown in FIG. 12, in another embodiment, the metal wiring layer 200 has a different shape, and the metal wiring layer 200 presents an I-shape on the cross-section shown in FIG. In this case, the manufacturing method of the corresponding circuit board 100 is also different. Specifically, in combination with the figures, the manufacturing method includes the following steps.

At a step 1100, a die 104 is formed (see FIG. 13, in conjunction with FIG. 12 if necessary).

The die 104 includes at least three metal wiring layers 200. One of the metal wiring layers 200 close to the first end portion 101 is referred to as the first wiring layer 210, one of the metal wiring layers 200 close to the second end portion 102 is referred to as the second wiring layer 220, and one of the metal wiring layers 200 located between the first wiring layer 210 and the second wiring layer 220 is referred to as the third wiring layer 230. An insulating layer 600 is further disposed between adjacent metal wiring layers 200.

This step specifically includes: the second wiring layer 220 is formed, and then the insulating layer 600 is formed thereon; then, a third wiring layer 230 is formed thereon; after the third wiring layer 2300 is formed, a hole is formed in a side of the third wiring layer 230 away from the second wiring layer 220, and a third sinking-groove 231 is formed in the third wiring layer 230; then, a transition material is deposited in the third sinking-groove 231 to form a deposited structure 232; and then, an insulating layer 600 and a first wiring layer 210 are formed on the third wiring layer 230.

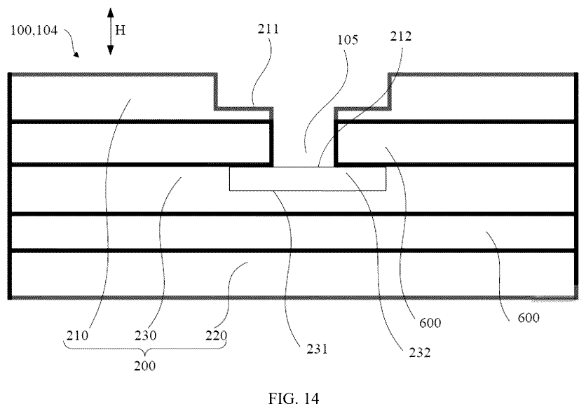

At a step 2100: a side of the die 104 away from the second wiring layer 220 is drilled, a first sinking-groove 105 is formed in the die 104, and the first sinking-groove 105 extends to the deposition structure 232 on the third wiring layer 230 (referring to FIG. 14, in conjunction with FIG. 12 if necessary).

In this embodiment, the first sinking-groove 105 may be formed by a high-energy UV laser ray cutting. In addition, the first sinking-groove 105 extends into the third wiring layer 230. Of course, in other embodiments, the first sinking-groove 105 may also extend to an end surface of the third wiring layer 230 away from the second wiring layer 220.

At a step 3100, which is the same as the previous embodiment, the side of the die 104 away from the second wiring layer 220 is drilled again, and a grounding sinking-groove 211 is formed in the die 104. The grounding sinking-groove 211 is located in the first wiring layer 210, and a projection of the grounding sinking-groove 211 on the second wiring layer 220 covers a projection of the first sinking-groove 105 on the second wiring layer 220. In other words, an area of a cross-section of the grounding sinking-groove 211 is greater than an area of a cross-section of the first sinking-groove 105. Meanwhile, an area of a cross-section of the third sinking-groove 231 may be the same as the area of the cross-section of the grounding sinking-groove 211.

In this embodiment, the grounding sinking-groove 211 may be formed by the high-energy UV laser ray cutting again. In this case, a part of the structure of the first sinking-groove 105 is located in the grounding sinking-groove 211, and the other part of the structure serves as the vertical sinking-groove 212 mentioned above. In this embodiment, the shape of the grounding sinking-groove 211 is circular. Of course, the cross-sectional shape of the grounding sinking-groove 211 is not unique. The cross-sectional shape of the grounding sinking-groove 211 can be changed by changing a shape of a tool. In other embodiments, the cross-sectional shape of the grounding sinking-groove 211 may be square, oval, rectangular, or other shapes.

At a step 3200, the deposition structure 232 in the third sinking-groove 231 is removed to expose the structure of the third sinking-groove 231.

At a step 4100, which is similar to the previous embodiment, carbon powder particles 106 are attached to wall surfaces of the grounding sinking-groove 211, the vertical sinking-groove 212 and the third sinking-groove 231. The function of the carbon powder particles is the same as that of the previous embodiment.

At a step 5100, which is similar to the previous embodiment, a metal material is deposited in the first sinking-groove 105, the grounding sinking-groove 211 and the third sinking-groove 231 to form the connection layer 300. A portion of the connection layer 300 located in the grounding sinking-groove 211 is referred to as a lateral extension portion 310, other portion of the connection layer 300 is referred to as a vertical extension portion 320, one end of the vertical extension portion 320 is connected to the lateral extension portion 310, and the other end of the vertical extension portion 320 extends to the metal material located in the third sinking-groove 231.

Through the above arrangement, not only the effect in the previous embodiment can be achieved, but also the contact area between the connection layer 300 and the third wiring layer 230 can be increased, so that the tight combination of the connection layer 300 and the third wiring layer 230 is ensured, the stability of the structure is ensured, and meanwhile, the stability of the electrical connection between the connection layer 300 and the third wiring layer 230 is improved.

At a step 6100: which is the same as the previous embodiment, the first wiring layer 210 is etched to reduce the area of the first wiring layer 210.

In the above steps, by reducing the lateral dimension of the first wiring layer 210, the thickness of the circuit board 100 at the corresponding position is reduced, so that when the circuit board 100 is bent, wound or folded at this position, the circuit board 100 is prevented from being broken at this position due to the thicker thickness. In other words, by reducing the thickness of the circuit board 100 at the corresponding position, the flexible deformation capability at the corresponding position is improved.

In this embodiment, the step of reducing the area of the first wiring layer 210 is performed after the step of forming the connection layer 300. Of course, in other embodiments, the step of reducing the area of the first wiring layer 210 may be performed before the step of forming the connection layer 300.

At a step 7100, which is the same as in the previous embodiment, cover layers 400 are individually formed on the first end portion 101 and the second end portion 102 of the circuit board 100.

Specifically, forming the cover layer 400 on the first end portion 101 of the circuit board 100 includes: forming the cover layer 400 on an end of the first wiring layer 210 away from the second wiring layer 220, a portion of the insulating layer 600 adjacent to the first wiring layer 210 exposed by etching the first wiring layer 210, and an end surface of a portion of the connection layer 300 exposed in the first wiring layer 210 away from the second wiring layer 220. The cover layer 400 may protect the film layer structure located therein.

At a step 8000, which is the same as the previous embodiment, shielding layers 500 are individually formed on the first end portion 101 and the second end portion 102 of the circuit board 100, and an oxidation layer 700 is formed on the second end portion 102.

Specifically, the shielding layer 500 is formed on an end of the cover layer 400 located at the first end portion 101 away from the second wiring layer 220. Another shielding layer 500 is formed on an end of the cover layer 400 located at the second end 102 away from the first wiring layer 210. Meanwhile, the oxidation layer 700 is formed on an end of the cover layer 400 located at the second end portion 102 away from the first wiring layer 210, and a gap exists between the oxidation layer 700 and the shielding layer 500.

Through the above arrangement, it is avoided that the step with the large slope appears in the circuit board 100, thereby avoiding or reducing the risk that the shielding layer 500 and the cover layer 400 are punctured, and further ensuring that the shielding layer 500 has effective ESD resistance and EMI resistance.

In the present disclosure, the structural embodiments and the method embodiments may be complementary to each other without conflict.

In the present disclosure, the terms “first”, “second”, and the like, are used for descriptive purposes only, and are not to be construed as indicating or implying relative importance. The terms “a plurality of/multiple” and “several” refer to two or more unless expressly defined otherwise.

A person skilled in the art will be able to easily conceive of other embodiments of the present disclosure after considering the specification and practice of the present disclosure disclosed herein. The present disclosure is intended to cover any variations, uses or adaptative changes of the present disclosure that follow the general principles of the present disclosure and include common knowledge or customary technical means in the art not disclosed herein. The specification and embodiments are to be regarded as exemplary only, and the actual scope and spirit of the present disclosure are indicated by the appended claims.

It should be understood that the present disclosure is not limited to the specific structures already described above and illustrated in the accompanying drawings, and that various modifications and changes may be made without departing from the scope thereof. The scope of the present disclosure is limited only by the appended claims.

1. A circuit board, comprising a first end portion and a second end portion disposed opposite to each other along a thickness direction, wherein the circuit board further comprises:
metal wiring layers, the number of the metal wiring layers being at least three, wherein a metal wiring layer of the metal wiring layers close to the first end portion is a first wiring layer, a metal wiring layer of the metal wiring layers close to the second end portion is a second wiring layer, and one or more metal wiring layers of the metal wiring layers located between the first wiring layer and the second wiring layer are located in a third wiring layer; and
a connection layer, comprising a lateral extension portion and a vertical extension portion that are electrically connected to each other, wherein at least part of the lateral extension portion is located in the first wiring layer, one end of the vertical extension portion is connected to the lateral extension portion, and the other end of the vertical extension portion extends to the third wiring layer.

2. The circuit board according to claim 1, wherein an end surface of the first wiring layer away from the third wiring layer is recessed downward to form a grounding sinking-groove, and the at least part of the lateral extension portion is located in the grounding sinking-groove.

3. The circuit board according to claim 2, wherein the grounding sinking-groove comprises a bottom surface, the bottom surface is recessed downward to form a vertical sinking-groove, the vertical sinking-groove communicates with the grounding sinking-groove, and in the thickness direction, an area of a projection of the vertical sinking-groove on the second wiring layer is less than an area of a projection of the grounding sinking-groove on the second wiring layer.

4. The circuit board according to claim 2, wherein a ratio of a depth of the grounding sinking-groove to a thickness of the first wiring layer is greater than or equal to ⅕ and less than or equal to ⅘.

5. The circuit board according to claim 1, wherein an end surface of the connection layer away from the second wiring layer is a first end surface, and an end surface of the first wiring layer away from the second wiring layer is a second end surface; and
a distance from the first end surface to the second end surface is less than or equal to 50 micrometers.

6. The circuit board according to claim 5, wherein the first end surface is recessed along a direction from the first wiring layer to the second wiring layer to form a groove.

7. The circuit board according to claim 6, wherein a depth of the groove is less than the distance from the first end surface to the second end surface.

8. The circuit board according to claim 1, wherein the circuit board comprises an encapsulation module, and the encapsulation module is disposed at a side of the first wiring layer away from the second wiring layer;
an area of a projection of the first wiring layer on the second wiring layer is less than an area of a projection of the third wiring layer on the second wiring layer, and the first wiring layer and the encapsulation module located on the first wiring layer form a convex island; and
a projection of the convex island on the second wiring layer covers a projection of the connection layer on the second wiring layer.

9. The circuit board according to claim 8, wherein the circuit board comprises a bending region, and the circuit board is capable of being bent in the bending region to form a crease; the convex island is located in the bending region, and a minimum distance from the crease to the convex island is greater than or equal to 0.1 mm.

10. The circuit board according to claim 1, wherein along the thickness direction, an area of a projection of the lateral extension portion on the second wiring layer is greater than or equal to 0.001 square millimeters and less than or equal to 0.1 square millimeters.

11. The circuit board according to claim 1, wherein the connection layer further comprises a connection portion located in the third wiring layer and electrically connected to the third wiring layer; and
one end of the vertical extension portion is connected to the lateral extension portion, and the other end of the vertical extension portion extends to the connection portion.

12. The circuit board according to claim 11, wherein an area of a projection of the vertical extension portion on the second wiring layer is less than an area of a projection of the connection portion on the second wiring layer.

13. A display panel, comprising a display module and the circuit board according to claim 1, wherein the display module is electrically connected to the circuit board.

14. A display device, comprising a housing and the display panel according to claim 13, wherein the display panel is fixed to the housing.

15. A method for manufacturing the circuit board according to claim 1, comprising:
providing a die, wherein the die comprises at least three metal wiring layers, a metal wiring layer of the metal wiring layers close to the first end portion is a first wiring layer, a metal wiring layer of the metal wiring layers close to the second end portion is a second wiring layer, and one or more metal wiring layers of the metal wiring layers located between the first wiring layer and the second wiring layer are located in a third wiring layer;
drilling a side of the die away from the second wiring layer, and forming a first sinking-groove in the die, the first sinking-groove extending to the third wiring layer;
drilling the side of the die away from the second wiring layer again, and forming a grounding sinking-groove in the die, wherein the grounding sinking-groove is located in the first wiring layer, and a projection of the grounding sinking-groove on the second wiring layer covers a projection of the first sinking-groove on the second wiring layer; and
forming a connection layer in the first sinking-groove and the grounding sinking-groove, wherein a part of the connection layer located in the grounding sinking-groove is a lateral extension portion, and the other part of the connection layer is a vertical extension portion, one end of the vertical extension portion is connected to the lateral extension portion, and the other end of the vertical extension portion extends to the third wiring layer.

16. The circuit board according to claim 5, wherein a plane where the first end surface is located is flush with a plane where the second end surface is located.

17. The circuit board according to claim 5, wherein the first end surface is farther away from the second wiring layer than the second end surface.

18. The circuit board according to claim 8, wherein an area of a projection of the lateral extension portion on the second wiring layer is a first area, an area of a projection of the first wiring layer located in the convex island on the second wiring layer is a second area, a ratio of the first area to the second area is greater than or equal to ¼ and less than or equal to ½.

19. The circuit board according to claim 8, wherein the encapsulation module comprises a cover layer disposed at a side of the first wiring layer away from the second wiring layer and a shielding layer disposed at a side of the cover layer away from the first wiring layer.

20. The circuit board according to claim 12, wherein an area of a projection of the lateral extension portion on the second wiring layer coincides with and is the same as an area of a projection of the connection portion on the second wiring layer.
